(19) United States
(12) Patent Application Publication
(10) Pub. No.: US 2020/0020686 A1
(43) Pub. Date: Jan. 16, 2020

(54) STACKED METAL-OXIDE-SEMICONDUCTOR, METAL-OXIDE-METAL, AND METAL-INSULATOR-METAL CAPACITORS

(71) Applicant: QUALCOMM Incorporated, San Diego, CA (US)

(72) Inventors: Junjing BAO, San Diego, CA (US); Yan WANG, San Diego, CA (US); Jie DENG, San Diego, CA (US); Giridhar NALLAPATI, San Diego, CA (US)

(21) Appl. No.: 16/035,387

(22) Filed: Jul. 13, 2018

(51) Int. Cl. H01L 27/08; H01L 29/94; H01L 29/66; H01L 49/02; H01L 23/522

(52) U.S. Cl. CPC H01L 27/0811; H01L 29/94; H01L 23/5223; H01L 28/60; H01L 29/66181

(57) ABSTRACT

An integrated circuit (e.g., a stacked capacitor) achieves higher capacitor density without additional area consumption. The integrated circuit includes a metal-oxide-semiconductor capacitor (MOSCAP), a metal-oxide-metal capacitor (MOMCAP) and a metal-insulator-metal capacitor (MIMCAP) stacked together. The MOSCAP includes a gate and source/drain (S/D) regions. The MOMCAP is included in back-end-of-line (BEOL) layers over the MOSCAP or supported by the MOSCAP.

### TECHNICAL FIELD

The present disclosure relates generally to semiconductor devices and, more particularly, to stacked metal-oxide-semiconductor (MOS), metal-oxide-metal (MOM), and metal-insulator-metal (MIM) capacitors.

### BACKGROUND

Mobile radio frequency (RF) chips (e.g., mobile RF transceivers) have migrated to a deep sub-micron process node due to cost and power consumption considerations. Designing mobile RF transceivers is further complicated by added circuit functions for supporting communication enhancements, such as carrier aggregation. Further design challenges for mobile RF transceivers include using passive devices, which directly affect analog/RF performance considerations, including mismatch, noise, and other performance considerations.

Passive devices may involve high performance capacitor components. For example, analog integrated circuits use various types of passive devices, such as integrated capacitors. These integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures.

MOM capacitors are also known as vertical parallel plate (VPP) capacitors, natural vertical capacitors (NVCAP), lateral flux capacitors, comb capacitors, as well as interdigitated finger capacitors. MOM capacitors exhibit beneficial characteristics including high capacitance density, low parasitic capacitance, superior RF characteristics, and good matching characteristics without additional masks or process steps relative to other capacitor structures.

MOM capacitors are one of the most widely used capacitors due to their beneficial characteristics. MOM capacitor structures realize capacitance by using the fringing capacitance produced by sets of interdigitated fingers. MOM capacitors comprise a dielectric, oxide, or insulating layer between two or more metal layers and include, but are not limited to, flux capacitors, fractal capacitors, parallel-plate capacitors, and woven capacitors. For example, MOM capacitors harness lateral capacitive coupling between plates formed by metallization layers and wiring traces.

Metal-oxide-semiconductor (MOS) capacitors and metal-oxide-metal (MOM) capacitors are used in many applications, such as in analog filters. MOS capacitors may also be referred to as metal-oxide-semiconductor varactors (MOSVARs) of either N- or P-type, having a capacitance that varies with applied voltage across their terminals. MOS capacitors are generally more area efficient than MOM capacitors and therefore can be used in place of MOM capacitors.

Another structure employed to increase capacitance is a metal-insulator-metal (MIM) capacitor. In its simplest configuration, a number of horizontal parallel plates of metal are stacked into several layers, separated by dielectrics. The plates are conductive and alternately coupled to form opposite electrodes of a capacitor. The vertical stack of plates is simple to construct, and offers more capacitance per unit area than two conductive surfaces alone. However, while simple to construct, forming a MIM capacitor with many layers often requires additional processing steps, which can add prohibitive cost to the manufacturing process.

### SUMMARY

An integrated circuit (IC) device may include a MOSCAP (metal-oxide-semiconductor capacitor) having a gate and source/drain (S/D) regions. The integrated circuit device further includes a MOMCAP (metal-oxide-metal capacitor) in back-end-of-line (BEOL) layers on the MOSCAP. The MOMCAP includes interdigitated fingers. The integrated circuit device also includes a MIMCAP (metal-insulator-metal capacitor) in different BEOL layers than the MOMCAP. The MIMCAP includes a dielectric between multiple plates.

A method of fabricating a stacked capacitor includes fabricating a MOSCAP (metal-oxide-semiconductor capacitor) having a gate and source/drain (S/D) regions. The method further includes fabricating a MOMCAP (metal-oxide-metal capacitor) in back-end-of-line (BEOL) layers on the MOSCAP. The MOMCAP includes interdigitated fingers. The method also includes fabricating a MIMCAP (metal-insulator-metal capacitor) in different BEOL layers than the MOMCAP. The MIMCAP includes a dielectric between multiple plates.

An integrated circuit (IC) device may include a MOSCAP (metal-oxide-semiconductor capacitor) having a gate and source/drain (S/D) regions. The integrated circuit device further includes a MOMCAP (metal-oxide-metal capacitor) in back-end-of-line (BEOL) layers on the MOSCAP. The MOMCAP includes interdigitated fingers. The integrated circuit device also includes means for storing electrical charge. The electrical charge storing means is in different BEOL layers than the MOMCAP.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 shows a wireless device communicating with a wireless system.

FIG. 2 shows a block diagram of the wireless device in FIG. 1.

FIG. 3 is a cross-section illustrating an integrated circuit (IC) device including an interconnect stack that contains conventional metal-oxide-metal (MOM) capacitor structures.

FIG. 4A illustrates a top view of a metal-oxide-metal (MOM) capacitor according to aspects of the present disclosure.

FIG. 4B illustrates a cross-section of conductive fingers of a metal-oxide-metal (MOM) capacitor that are arranged in accordance with an orthogonal configuration.

FIG. 4C illustrates a cross-section of conductive fingers of a metal-oxide-metal (MOM) capacitor that are arranged in accordance with a parallel configuration.

FIG. 5 is a schematic diagram illustrating a single metal-oxide-semiconductor (MOS) capacitor according to aspects of the present disclosure.

FIG. 6 is a schematic diagram illustrating a dual metal-oxide-semiconductor (MOS) capacitor according to aspects of the present disclosure.

FIG. 7A and FIG. 7B are respectively a cross-section of a metal-insulator-metal capacitor (MIMCAP) and a top-down view of the MIMCAP.

FIG. 8 illustrates a stacked capacitor including a metal-oxide-semiconductor capacitor (MOSCAP), a metal-oxide-metal capacitor (MOMCAP) and a metal-insulator-metal capacitor (MIMCAP) according to aspects of the present disclosure.

FIG. 9 illustrates a method of fabricating a stacked capacitor according to aspects of the present disclosure.

FIG. 10 is a block diagram showing an exemplary wireless communications system in which an aspect of the disclosure may be advantageously employed.

FIG. 11 is a block diagram illustrating a design workstation used for circuit, layout, and logic design of a stacked capacitor disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

It is desirable to provide capacitors with high capacitance and small footprint (e.g. unit area capacitance) for analog designs such as analog-to-digital converters (ADC), phase lock loops (PLLs), etc. The process flow for fabrication of the capacitor may include front-end-of-line (FEOL) processes, middle-of-line (MOL) processes, and back-end-of-line (BEOL) processes. The back-end-of-line interconnect layers may refer to the conductive interconnect layers (e.g., a first interconnect layer or metal one (M1), metal two (M2), metal three (M3), metal four (M4), etc.) for electrically coupling to front-end-of-line active devices of an integrated circuit. The various back-end-of-line interconnect layers are formed at corresponding back-end-of-line interconnect levels, in which lower back-end-of-line interconnect levels use thinner metal layers relative to upper back-end-of-line interconnect levels. The back-end-of-line interconnect layers may electrically couple to middle-of-line interconnect layers, for example, connecting the M1 layer to an oxide diffusion (OD) layer of an integrated circuit.

The middle-of-line interconnect layer may include a zero interconnect layer (M0) for connecting the M1 layer to an active device layer of an integrated circuit. A back-end-of-line first via (V2) may connect the M2 layer to the M3 layer or others of the back-end-of-line interconnect layers. It will be understood that the term “layer” includes film and is not to be construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Certain foundries and processes may allow vertical or other means of integration of two different capacitors, allowing fabrication of a stacked capacitor (stackcap). A stackcap generally has a very dense architecture as it combines the area density of both of the different capacitors, and accordingly, consumes a small amount of circuit area. Unfortunately, when used in high density circuit applications, it may be challenging to design the stackcap to achieve increased capacitance while maintaining a small footprint. For example, stacking capacitors may lead to non-linearities, may prevent a stackcap-only capacitor implementation, and may lead to the need for, or substitution of, additional capacitors that are not part of the stack-cap to achieve better linearity.

Therefore, a stacked capacitance with increased capacitance that reduces or minimizes circuit area is desirable. For example, it is desirable to provide capacitors with high capacitance and small footprint (e.g. unit area capacitance) for different electronic designs. Some stackcaps include metal-oxide-semiconductor metal-oxide-metal (MOS_MOM) capacitors or metal-oxide-metal metal-insulator-metal (MOM_MIM) capacitors. However, these stackcaps may not satisfy ever increasing capacitance specifications.

Aspects of the present disclosure are directed to an integrated circuit (e.g., a stacked capacitor or stackcap) for achieving higher capacitor density (thus, higher performance of the capacitor) without additional area consumption. The integrated circuit includes a metal-oxide-semiconductor capacitor (MOSCAP), a metal-oxide-metal capacitor (MOMCAP) and a metal-insulator-metal capacitor (MIMCAP) stacked together. The MOSCAP includes a gate and source/drain (S/D) regions. The MOMCAP is included in back-end-of-line (BEOL) layers over the MOSCAP or supported by the MOSCAP. Of course, being “over” is based on the orientation of the MOSCAP and the present disclosure is not limited to a particular orientation. The MOMCAP includes interdigitated fingers. The MIMCAP is included in other layers of the BEOL layers that are different from the layers in which the MOMCAP is included. The MIMCAP includes a dielectric between multiple plates.

Electrodes or terminals (e.g., anodes and cathodes) of the stacked capacitor are coupled to each other as part of the fabrication process so an end user does not have to manually connect the anodes and the cathodes of the stacked capacitor. For example, the MOSCAP includes a first cathode and a first anode, the MOMCAP includes a second cathode and a second anode, and the MIMCAP includes a third cathode and a third anode. The first, the second, and the third anodes are coupled together while the first, the second, and the third cathodes are coupled together. A total capacitance (C_{TOTAL}) of the stacked capacitor is equal to a sum of a capacitance of the MOSCAP (C_{MOS}), a capacitance of the MOMCAP (C_{MOM}), and a capacitance of the MIMCAP (C_{MIM}).

In some aspects of the present disclosure, the MIMCAP is between the MOSCAP and the MOMCAP. For example, the MOMCAP may be over the MIMCAP. In other aspects of the present disclosure, the MOMCAP is between the MOSCAP and the MIMCAP. For example, the MIMCAP may be over the MOMCAP. The stacked capacitor may be arrayable as a built-in option. The stacked capacitor arrays should have full conductive (metal) connections between individual stacked capacitors. For example, if the stacked capacitor includes interconnect layers M1-M7, all seven interconnect layers, instead of only the top interconnect layers, are used to connect the array. In one aspect of the disclosure, the MOSCAP is coupled to the MIMCAP or the MOMCAP with multiple vias to achieve strong connections to improve a quality factor of the stacked capacitor. Similarly, the MIMCAP is coupled to the MOSCAP with multiple vias. The stacked capacitor may be configured for high voltage and low voltage options. For example, the low voltage option is achieved with a thin oxide core MOSCAP, a narrow finger space MOMCAP and a thin dielectric MIMCAP. The high voltage option is achieved with a thick oxide I/O MOSCAP, a wide finger space MOMCAP and a thick dielectric MIMCAP.

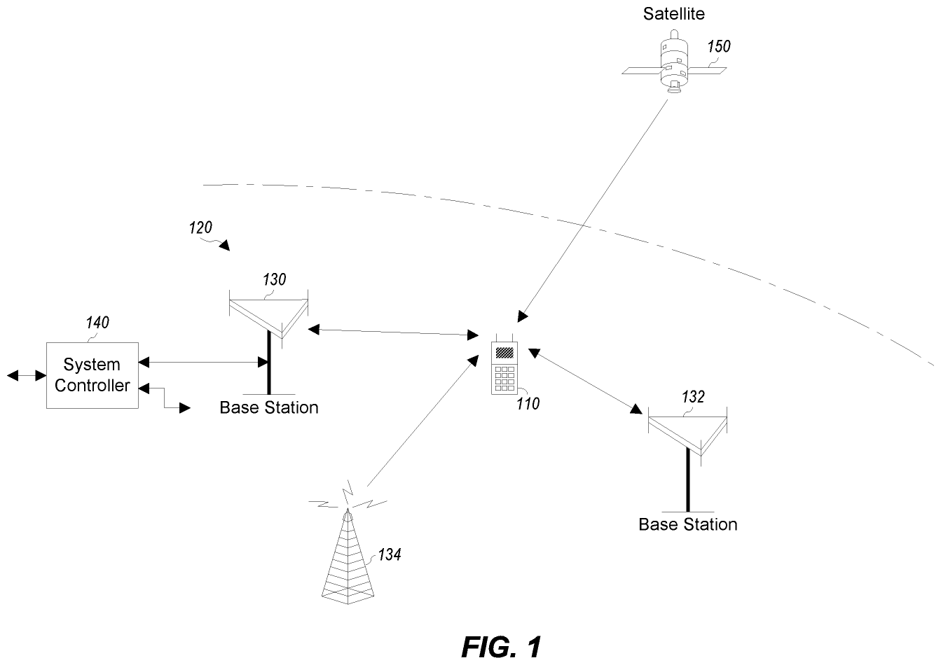

FIG. 1 shows a wireless device 110 communicating with a wireless communications system 120, according to aspects of the present disclosure. The wireless device may include the stacked capacitor, according to aspects of the present disclosure. The wireless communications system 120 may be a fifth generation (5G) system, a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communications system 120 including two base stations 130 and 132 and one system controller 140. In general, a wireless system may include any number of base stations and any number of network entities.

A wireless device 110 may also be referred to as a user equipment (UE). The user equipment may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. The wireless device 110 may be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. For example, the wireless device 110 may support Bluetooth low energy (BLE)/BT (Bluetooth) with a low energy/high efficiency power amplifier having a small form factor of a low cost.

The wireless device 110 may be capable of communicating with the wireless communications system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communications such as 5G, LTE, CDMA2000, WCDMA, TD-SCDMA, GSM, 802.11, BLE/BT, etc. The wireless device 110 may also support carrier aggregation, which is operation on multiple carriers.

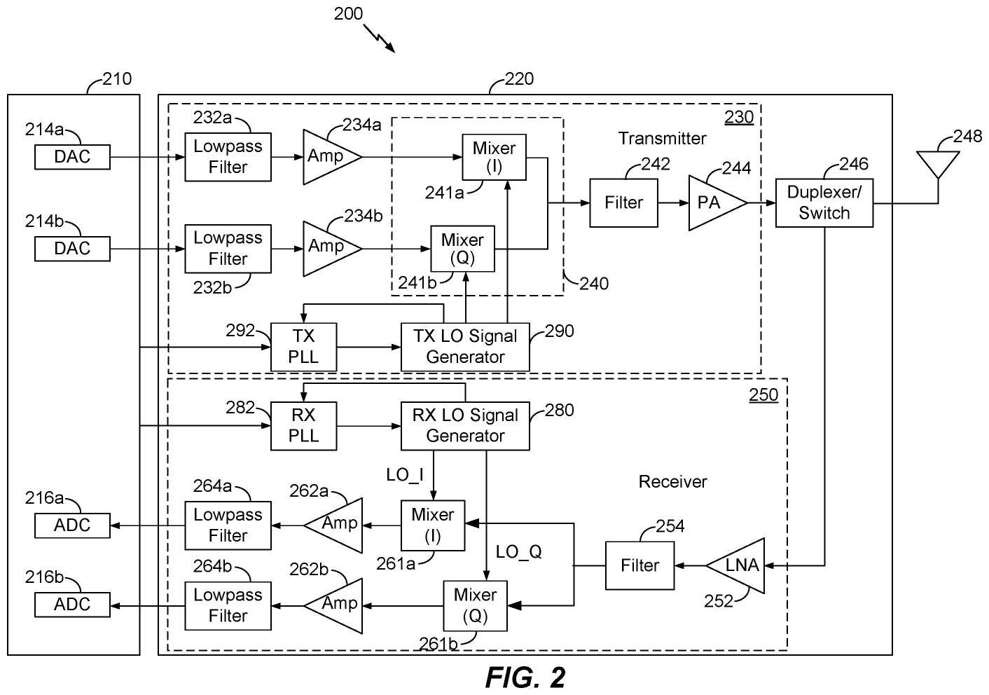

FIG. 2 shows a block diagram of an exemplary design of a wireless device 200, such as the wireless device 110 shown in FIG. 1, including a fully integrated differential hard-switching radio frequency (RF) power amplifier with harmonic rejection, according to aspects of the present disclosure. FIG. 2 shows an example of a mobile RF transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 1. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, the wireless device 200 generally includes the mobile RF transceiver 220 and a data processor 210. The data processor 210 may include a memory (not shown) to store data and program codes, and may generally include analog and digital processing elements. The mobile RF transceiver 220 may include the transmitter 230 and receiver 250 that support bi-directional communication. In general, the wireless device 200 may include any number of transmitters and/or receivers for any number of communications systems and frequency bands. All or a portion of the mobile RF transceiver 220 may be implemented on one or more analog integrated circuits (ICs), radio frequency (RF) integrated circuits (RFICs), mixed-signal ICs, and the like.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog-converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to remove undesired images caused by the prior digital-to-analog conversion. Amplifiers 234a and 234b (Amp) amplify the signals from lowpass filters 232a and 232b, respectively, and provide in-phase (I) and quadrature (Q) baseband signals. Upconverters 240 include an in-phase upconverter 241a and a quadrature upconverter 241b that upconverter the in-phase (I) and quadrature (Q) baseband signals with in-phase (I) and quadrature (Q) transmit (TX) local oscillator (LO) signals from a TX LO signal generator 290 to provide upconverted signals. A filter 242 filters the upconverted signals to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248. The duplexer/switch 246, however, introduces significant insertion loss in a communication path. This follows because the duplexer is placed after the power amplifier 244 and in close proximity to the antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital-converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

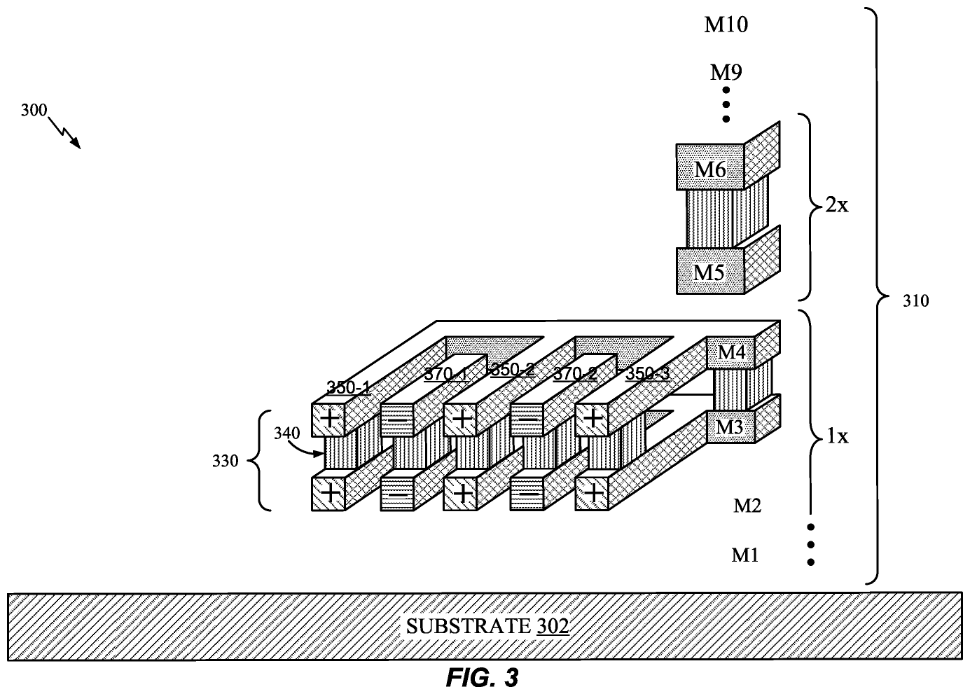

Capacitors are widely used in analog integrated circuits. FIG. 3 is a block diagram illustrating a cross-section of an analog integrated circuit (IC) device 300 including an interconnect stack 310. The interconnect stack 310 of the IC device 300 includes multiple conductive interconnect layers (M1, . . . , M9, M10) on a semiconductor substrate (e.g., a diced silicon wafer) 302. The semiconductor substrate 302 supports a metal-oxide-metal (MOM) capacitor 330. In this example, the MOM capacitor 330 is formed in the M3 and M4 interconnect layers, below the M5 and M6 interconnect layers. The MOM capacitor 330 is formed from lateral conductive fingers of different polarities using the conductive interconnect layers (M3 and M4) of the interconnect stack 310. A dielectric (not shown) is provided between the conductive fingers.

In this example, the MOM capacitor 330 is formed within the lower conductive interconnect layers (e.g., M1-M4) of the interconnect stack 310. The lower conductive interconnect layers of the interconnect stack 310 have smaller interconnect widths and spaces. For example, the dimensions of the conductive interconnect layers M3 and M4 are half the size of the dimensions of the conductive interconnect layers M5 and M6. Likewise, the dimensions of the conductive interconnect layers M1 and M2 are half the size of the dimensions of the conductive interconnect layers M3 and M4. The small interconnect widths and spaces of the lower conductive interconnect layers enable the formation of MOM capacitors with increased capacitance density.

As shown in FIG. 3, the MOM capacitor 330 makes use of a inter layer capacitive coupling 340 between fingers (e.g., 350, 370) formed by standard metallization of the conductive interconnects (e.g., wiring lines and vias). The inter layer coupling 340 within the MOM capacitor 330 provides improved matching characteristics.

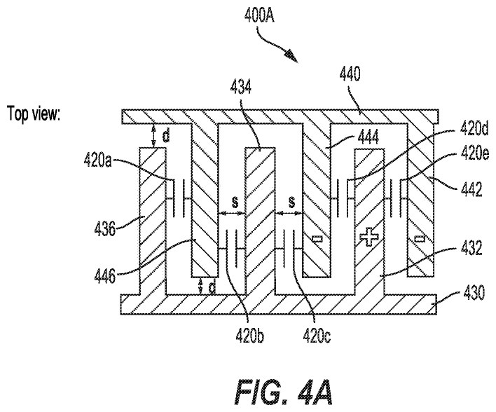

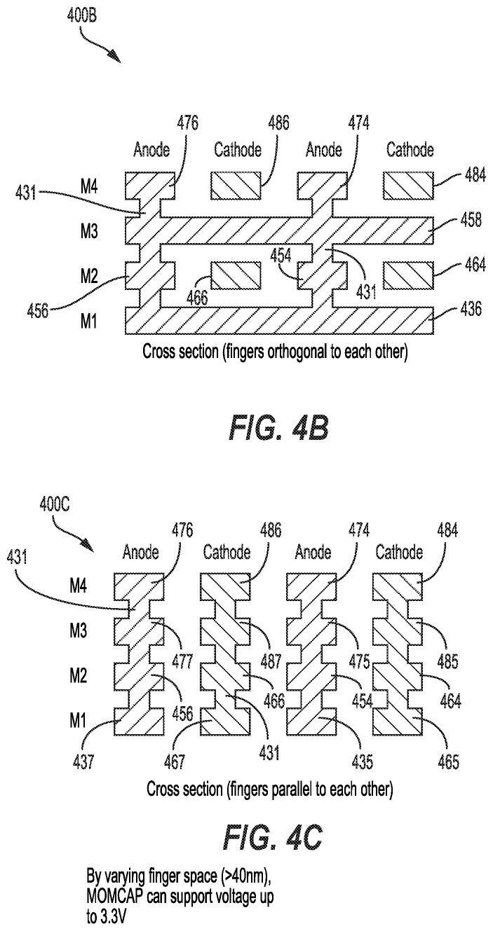

FIG. 4A illustrates a top view of a metal-oxide-metal capacitor (MOMCAP) 400A, according to aspects of the present disclosure. The MOMCAP 400A may be fabricated in one or more BEOL interconnect levels/layers (e.g., M1-M4) such as the multiple conductive interconnect layers (e.g., M1, . . . , M9, M10).

The top view of the MOMCAP 400A includes a first capacitor routing terminal (e.g., endcap or manifold) 430 and a second endcap 440. The first endcap 430 is parallel to the second endcap 440. The first endcap 430 is of a first polarity (e.g., positive or anode) while the second endcap 440 is of a second polarity (e.g., negative or cathode). A first set of parallel conductive capacitor routing traces (e.g., conductive fingers) of the MOMCAP 400A includes a first conductive finger 432, a second conductive finger 434, and a third conductive finger 436.

Each of the first conductive finger 432, the second conductive finger 434, and the third conductive finger 436 is orthogonally coupled to the first endcap 430. Each of the first conductive finger 432, the second conductive finger 434, and the third conductive finger 436 is of the first polarity.

A second set of parallel conductive fingers of the MOMCAP 400A includes a fourth conductive finger 442, a fifth conductive finger 444, and a sixth conductive finger 446. Each of the fourth conductive finger 442, the fifth conductive finger 444, and the sixth conductive finger 446 is orthogonally coupled to the second endcap 440. Each of the fourth conductive finger 442, the fifth conductive finger 444, and the sixth conductive finger 446 is of the second polarity.

The first set of parallel conductive fingers are interdigitated with the second set of parallel conductive fingers at a first interconnect layer to form an array of capacitances 420 (including a first capacitance 420a, a second capacitance 420b, a third capacitance 420c, a fourth capacitance 420d, and a fifth capacitance 420e) between the conductive fingers of the first polarity and the conductive fingers of the second polarity. For example, the second capacitance 420b of the array of capacitances 420 is formed between the second conductive finger 434, which is a conductive finger of the first polarity and the sixth conductive finger 446, which is a conductive finger of the second polarity. The third capacitance 420c of the array of capacitances 420 is formed between the second conductive finger 434 and the fifth conductive finger 444.

The first endcap 430 is parallel to the second endcap 440 such that a first gap d separates the first set of parallel conductive fingers from the second endcap 440 and a second gap d separates the second set of parallel conductive fingers from the first endcap 430. The first set of parallel conductive fingers is interdigitated with the second set of parallel conductive fingers at a first interconnect layer such that a third gap S separates each of the first set of parallel conductive fingers from one or more adjacent second set of parallel conductive fingers. By varying conductive finger spaces (e.g., >40 nanometer) a MOMCAP (e.g., MOMCAP 400A) may support voltages up to 3.3 volts.

FIG. 4B illustrates a cross-section 400B of conductive fingers of a metal-oxide-metal (MOM) capacitor that are arranged in accordance with an orthogonal configuration. For example, the cross-section 400B may be of the MOMCAP 400A. For illustrative purposes, some of the labelling and numbering of the devices and features of FIG. 4B are similar to those of FIG. 4A.

The cross-section 400B illustrates multiple conductive interconnect layers (e.g., a first conductive interconnect layer M1, a second conductive interconnect layer M2, a third conductive interconnect layer M3, and a fourth conductive interconnect layer M4). Each of the conductive interconnect layers includes conductive fingers. For example, the first conductive interconnect layer M1 includes a conductive finger 436. The second conductive interconnect layer M2 includes conductive fingers 454, 456, 464, and 466. The third conductive interconnect layer M3 includes a conductive finger 458. The fourth conductive interconnect layer M4 includes conductive fingers 474, 476, 484, and 486. The conductive fingers of the first conductive interconnect layer M1 (e.g., conductive finger 436) and the third conductive interconnect layer M3 (e.g., conductive finger 458) are orthogonal to the conductive fingers of the second conductive interconnect layer M2 (e.g., conductive fingers 454, 456, 464, and 466) and the conductive fingers of the fourth conductive interconnect layer M4 (e.g., conductive fingers 474, 476, 484, and 486). Conductive fingers of a same polarity in different conductive layers are coupled together by vias 431.

FIG. 4C illustrates a cross-section 400C of conductive fingers of a metal-oxide-metal (MOM) capacitor arranged in accordance with a parallel configuration. For example, the cross-section 400C may be of the MOMCAP 400A. For illustrative purposes, some of the labelling and numbering of the devices and features of FIG. 4C are similar to those of FIGS. 4A and 4B.

The cross-section 400C illustrates multiple conductive interconnect layers (e.g., the first conductive interconnect layer M1, the second conductive interconnect layer M2, the third conductive interconnect layer M3, and the fourth conductive interconnect layer M4). Each of the conductive interconnect layers includes conductive fingers. For example, the first conductive interconnect layer M1 includes conductive finger 435, 437, 465, and 467. The second conductive interconnect layer M2 includes conductive fingers 454, 456, 464, and 466. The third conductive interconnect layer M3 includes conductive fingers 475, 477, 485, and 487. The fourth conductive interconnect layer M4 includes conductive fingers 474, 476, 484, and 486. In one aspect, the conductive fingers 435, 437, 454, 456, 475, 477, 474, and 476 are of the first polarity while the conductive fingers 465, 467, 464, 466, 485, 487, 484, and 486 are of the second polarity. In each conductive layer, the conductive fingers of the first polarity are arranged in an alternative configuration with respect to the conductive fingers of the second polarity.

The conductive fingers in each of the conductive layers are arranged in accordance with a parallel configuration relative to the conductive fingers in different conductive layers. For example, the conductive fingers of the first conductive interconnect layer M1 (e.g., conductive finger 435, 437, 465, and 467) and the third conductive interconnect layer M3 (e.g., conductive fingers 475, 477, 485, and 487) are parallel to the conductive fingers of the second conductive interconnect layer M2 (e.g., conductive fingers 454, 456, 464, and 466) and the conductive fingers of the fourth conductive interconnect layer M4 (e.g., conductive fingers 474, 476, 484, and 486). Conductive fingers of a same polarity in different conductive layers are coupled together by vias 431.

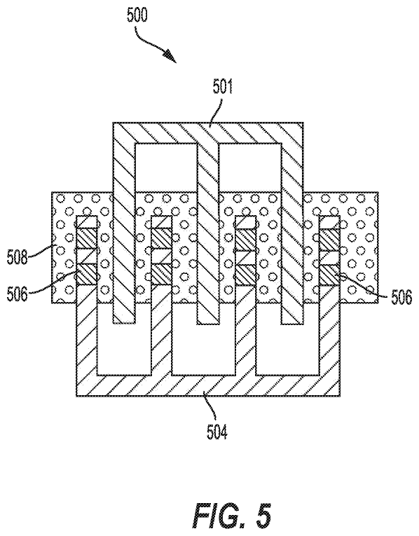

FIG. 5 is a schematic diagram (e.g., top-down view) illustrating a semiconductor device 500 that includes a single metal-oxide-semiconductor capacitor (MOSCAP) and a transistor (e.g., a field effect transistor), according to aspects of the present disclosure. MOS capacitors may also be referred to as metal-oxide-semiconductor varactors (MOSVARs) of either N- or P-type, having capacitance, which varies with applied voltage across their terminals. The MOSCAP and the transistor may be mounted on a semiconductor (e.g., silicon) substrate (not shown). The semiconductor substrate may be P-type or N-type semiconductor substrate. The semiconductor device 500 includes conductive layers such as electrodes for the MOSCAP, the transistor, and/or shared between the MOSCAP and the transistor. The transistor may have a gate as well as source/drain electrodes. For example, the transistor includes a gate electrode 501 as well as source/drain electrodes 504. The gate electrode 501 may be the anode and the source/drain electrodes 504 may be the cathode of the transistor. The cathode may be accessible for connection using vias 506 in the substrate.

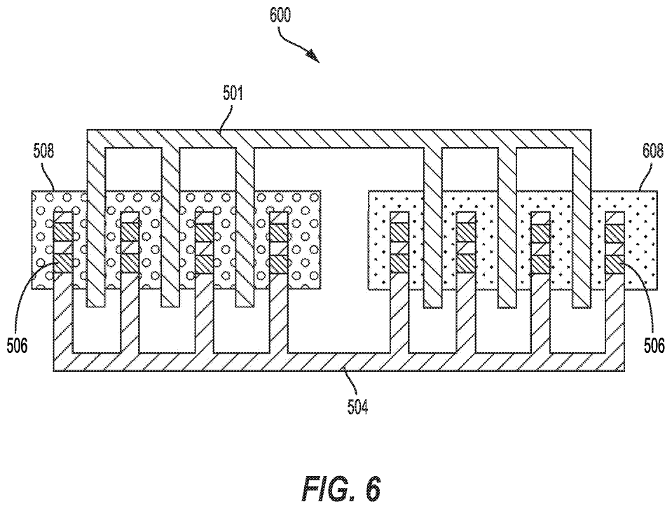

The field effect transistor and the MOSCAP have a shared oxide layer (not shown), such as silicon oxide layer. The oxide layer of the field effect transistor acts as a gate insulating layer while the oxide layer of the MOSCAP acts as a capacitance insulating layer or dielectric. A diffusion region 508 is defined adjacent (e.g., under) the oxide layer. For example, the oxide layer is between the gate electrode 501 and the diffusion region 508. The diffusion region 508 may be doped to form a desired electrode. For example, the diffusion region 508 may be doped to form an N-type electrode or a P-type electrode. The gate electrode 501 may also act as a first (e.g., top) electrode/plate for the MOSCAP while the diffusion region 508 is a second (e.g., bottom) electrode/plate of the MOSCAP. A capacitance of the MOSCAP may also include gate-to-source capacitance. For example, the gate electrode 501 may form a first plate of the MOSCAP and the source/drain electrodes 504 may form a second plate of the MOSCAP. The single MOSCAP may be an N-type MOSCAP or a P-type MOSCAP or a combination of an N-type MOSCAP and a P-type MOSCAP, as illustrated in FIG. 6.

FIG. 6 is a schematic diagram (e.g., top-down view) illustrating a semiconductor device 600 that includes a dual metal-oxide-semiconductor capacitor (MOSCAP) and a transistor (e.g., a field effect transistor), according to aspects of the present disclosure. For illustrative purposes, some of the labelling and numbering of the devices and features of FIG. 6 are similar to those of FIG. 5. Several of these MOSCAPs may form a MOS varactor (MOSVAR). The dual MOSCAP includes a combination of an N-type MOSCAP and a P-type MOSCAP. The diffusion region 508 may be doped to form an N-type electrode and a second diffusion region 608 may be doped to form a P-type electrode.

For example, a first MOSCAP associated with the diffusion region 508 that is doped to form an N-type electrode forms the N-type MOSCAP in conjunction with the gate electrode 501, conductive layer, and the oxide layer. A second MOSCAP associated with the diffusion region 608 that is doped to form the P-type electrode forms the P-type MOSCAP in conjunction with the gate electrode 501, conductive layer, and the oxide layer.

The MOSCAP may be used for low voltage (e.g., ˜0.75V) and high voltage (e.g., ˜1.8V) applications. The MOSCAP and the MOSVAR capacitance are voltage dependent. This follows because a MOSCAP is a combination of oxide and voltage dependent semiconductor capacitances. Unfortunately, MOS capacitors may exhibit non-linearity caused by capacitance variation with respect to voltage. MOSCAPs are generally more area efficient than MOMCAPs and therefore can be used in place of or in conjunction with MOMCAPs in a stackcap architecture to save circuit area.

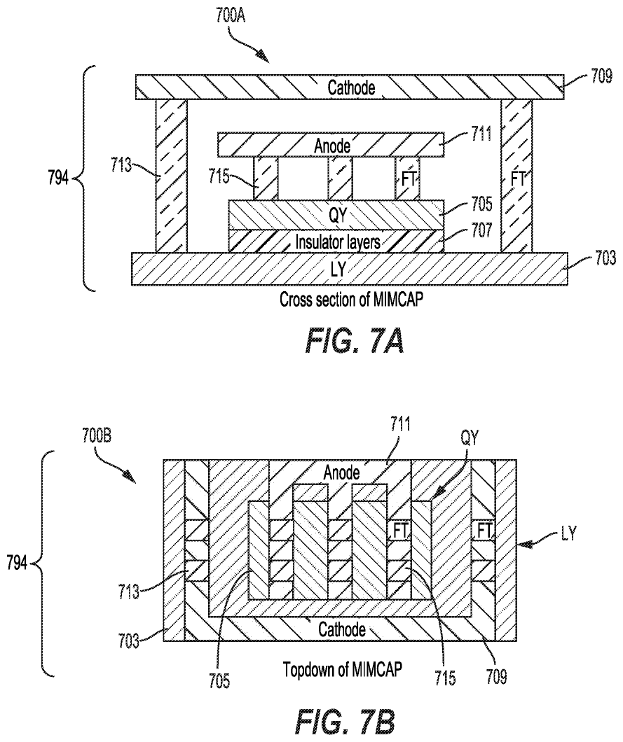

FIG. 7A and FIG. 7B are respectively a cross-section 700A of a metal-insulator-metal capacitor (MIMCAP) 794 and a top-down view 700B of the MIMCAP 794. The MIMCAP 794 may be supported by a substrate (e.g., a semiconductor substrate). The MIMCAP 794 may include a first conductive trace 703 in one conductive layer, a second conductive trace 705 in a different conductive layer, and a dielectric 707 (e.g., insulator material) between the first conductive trace 703 and the second conductive trace 705. The first conductive trace 703 and the second conductive trace 705 constitute top and bottom plates of the MIMCAP 794.

In one aspect of the disclosure, the terminals for the MIMCAP 794 are formed in different conductive layers than the first conductive trace 703 and the second conductive trace 705. For example, a polarity terminal (e.g., cathode) 709 may be formed on a conductive layer and coupled to the first conductive trace 703 in a different conductive layer by vias 713. A polarity terminal (e.g., anode) 711 may be formed on a conductive layer and coupled to the second conductive trace 705 in a different conductive layer by vias 715. By tuning a thickness (e.g., 10-20 nanometers) or property (e.g., high K material HfO2, HfZrO2) of the insulator material of the dielectric 707, the MIMCAP 794 can be configured to support up to 1.8 volts with leakage of less than 100 nanoamperes per centimeter squared. The high K material may be Hafnium(IV) oxide (HfO2) or hafnium zirconium oxide (HfZrO2).

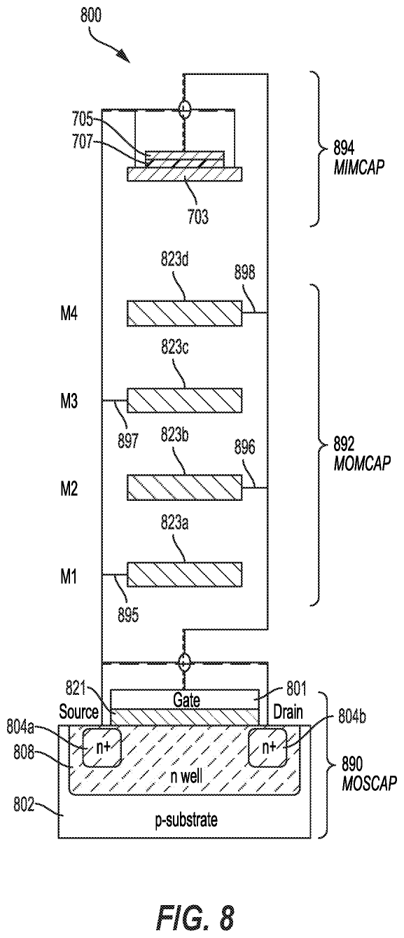

FIG. 8 illustrates a stacked capacitor 800 including a metal-oxide-semiconductor capacitor (MOSCAP) 890, a metal-oxide-metal capacitor (MOMCAP) 892, and a metal-insulator-metal capacitor (MIMCAP) 894, according to aspects of the present disclosure. For illustrative purposes, some of the labelling and numbering of the devices and features of FIG. 8 are similar to those of FIGS. 7A and 7B.

The stacked capacitor 800 includes the MOSCAP 890, the MOMCAP 892, and the MIMCAP 894 stacked together on a substrate 802. The MOSCAP 890 includes a gate 801 (e.g., the gate electrode 501 of FIG. 5), source/drain (S/D) regions 804a and 804b (e.g., source/drain electrodes 504), and a diffusion region 808 (e.g., the diffusion region 508 or 608). The MOSCAP 890 also includes a dielectric 821 (e.g., the oxide layer discussed with reference to FIG. 5). The MOMCAP 892 (e.g., the MOMCAP 400A) is included in back-end-of-line (BEOL) layers fabricated on or over the MOSCAP 890 or is supported by the MOSCAP 890. Of course, being “over” is based on the orientation of the MOSCAP 890. The MOMCAP 892 includes interdigitated fingers. The MIMCAP 894 is included in other layers of the BEOL layers that are different from the layers in which the MOMCAP 892 is included. The MIMCAP 894 includes a dielectric between a set of plates.

Electrodes or terminals (e.g., anodes and cathodes) of the stacked capacitor are coupled to each other as part of the fabrication process so an end user does not have to manually connect the anodes and the cathodes of the stacked capacitor. For example, the MOSCAP 890 includes a first cathode (e.g., the source/drain regions 804a and 804b) and a first anode (e.g., the gate 801).

The MOMCAP 892 is dispersed across multiple conductive layers including conductive layers M1, M2, M3, and M4 similar to the conductive layers of the MOMCAP 400A. Each conductive layer M1, M2, M3, and M4 includes a first portion 823a, a second portion 823b, a third portion 823c, and a fourth portion 823d, respectively, of the MOMCAP 892. For example, each portion of the MOMCAP 892 may be configured as the top view illustrated in FIG. 4A, where the conductive fingers of the positive polarity are coupled to the positive electrode (e.g., anode or first endcap 430) and conductive fingers of the negative polarity are coupled to the negative electrode (e.g., cathode or second endcap 440) of the MOMCAP 400A.

For simplicity, interconnects 896 and 898 are connected to the anodes (e.g., first endcap 430 as shown in FIG. 4A) of the second portion 823b and the fourth portion 823d of the MOMCAP 892, and interconnects 895 and 897 are connected to the cathodes (e.g., second endcap 440 as shown in FIG. 4A) of the first portion 823a and the third portion 823c of the MOMCAP 892. However, other interconnects (not shown) may be connected to cathodes of the second portion 823b and the fourth portion 823d of the MOMCAP 892 so that all cathodes of the stacked capacitor 800 are connected together. Similarly, other interconnects (not shown) may be connected to anodes of the first portion 823a and the third portion 823c of the MOMCAP 892 so that all anodes of the stacked capacitor 800 are connected together.

The anode or gate 801 of the MOSCAP 890 is connected to the interconnects 896 and 898, which are connected to the anodes (e.g., first endcap 430 as shown in FIG. 4A) of the second portion 823b and the fourth portion 823d of the MOMCAP 892. The cathode or source/drain (S/D) regions 804a and 804b of the MOSCAP 890 are connected to the interconnects 895 and 897, which are connected to the cathodes of the first portion 823a and the third portion 823c of the MOMCAP 892.

The MIMCAP 894 may include the first conductive trace 703 in one conductive layer and the second conductive trace 705 in a different conductive layer, and a dielectric 707 (e.g., insulator material) between the first conductive trace 703 and the second conductive trace 705. The first conductive trace 703, (which is connected to the polarity terminal (e.g., cathode) 709 of the MIMCAP, as shown in FIGS. 7A and 7B) is connected to the cathode or source/drain (S/D) regions 804a and 804b of the MOSCAP 890 and to the interconnects 895 and 897. The interconnects 895 and 897 are connected to the cathodes of the first portion 823a and the third portion 823c of the MOMCAP 892. The second conductive trace 705 (which is connected to the polarity terminal (e.g., cathode) 711 of the MIMCAP, as shown in FIGS. 7A and 7B) is connected to the anode or gate 801 of the MOSCAP 890 and to the interconnects 896 and 898. The interconnects 896 and 898 are connected to the anodes of the second portion 823b and the fourth portion 823d of the MOMCAP 892.

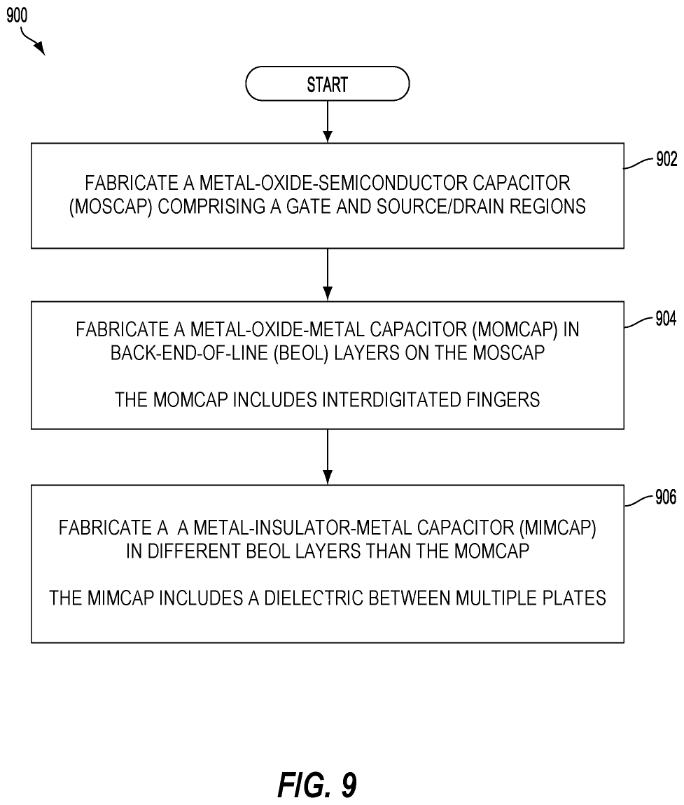

FIG. 9 illustrates a method 900 of fabricating a stacked capacitor (e.g., a stacked metal-oxide-semiconductor (MOS) capacitor, metal-oxide-metal (MOM) capacitor and metal-insulator-metal (MIM) capacitor) according to aspects of the present disclosure. The blocks in the method 900 can be performed in or out of the order shown, and in some aspects, can be performed at least in part in parallel. At block 902, a metal-oxide-semiconductor capacitor (MOSCAP) including a gate and source/drain (S/D) regions is fabricated. At block 904, a metal-oxide-metal capacitor (MOMCAP) is fabricated in back-end-of-line (BEOL) layers on the MOSCAP. The MOMCAP includes interdigitated fingers. At block 906, a metal-insulator-metal capacitor (MIMCAP) is fabricated in the BEOL layers. The MIMCAP is in different BEOL layers than the MOMCAP. The MIMCAP has a dielectric between a set of plates.

According to a further aspect of the present disclosure, a stacked capacitor is described. The stacked capacitor includes means for storing electrical charge. The electrical charge storing means, for example, include the MIMCAP 794, as shown in FIG. 7, and/or the MIMCAP 894, as shown in FIG. 8. In another aspect, the aforementioned means may be any module, or any apparatus configured to perform the functions recited by the aforementioned means.

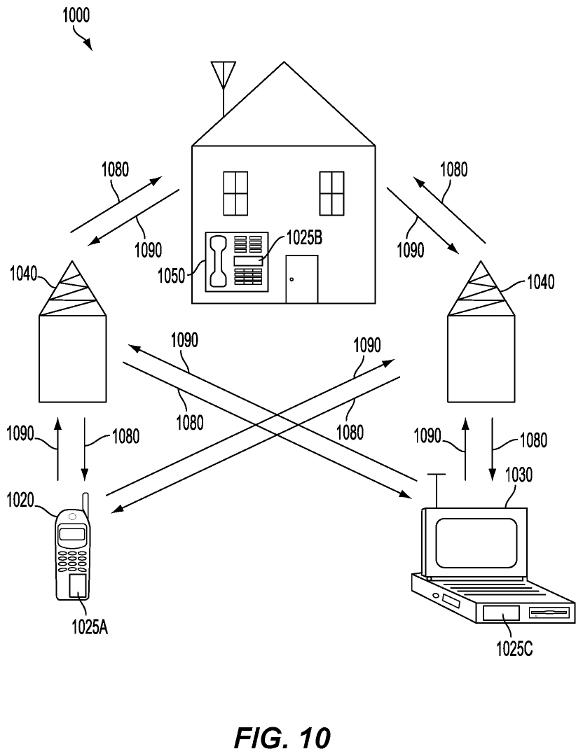

FIG. 10 is a block diagram showing an exemplary wireless communications system 1000 in which an aspect of the disclosure may be advantageously employed. For purposes of illustration, FIG. 10 shows three remote units 1020, 1030, and 1050 and two base stations 1040. It will be recognized that wireless communications systems may have many more remote units and base stations. Remote units 1020, 1030, and 1050 include IC devices 1025A, 1025C, and 1025B that include the disclosed stacked capacitor. It will be recognized that other devices may also include the disclosed stacked capacitor, such as the base stations, user equipment, and network equipment. FIG. 10 shows forward link signals 1080 from the base station 1040 to the remote units 1020, 1030, and 1050 and reverse link signals 1090 from the remote units 1020, 1030, and 1050 to base station 1040.

In FIG. 10, remote unit 1020 is shown as a mobile telephone, remote unit 1030 is shown as a portable computer, and remote unit 1050 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 10 illustrates remote units according to the aspects of the disclosure, the disclosure is not limited to these exemplary illustrated units. Aspects of the disclosure may be suitably employed in many devices, which include the disclosed stacked capacitor.

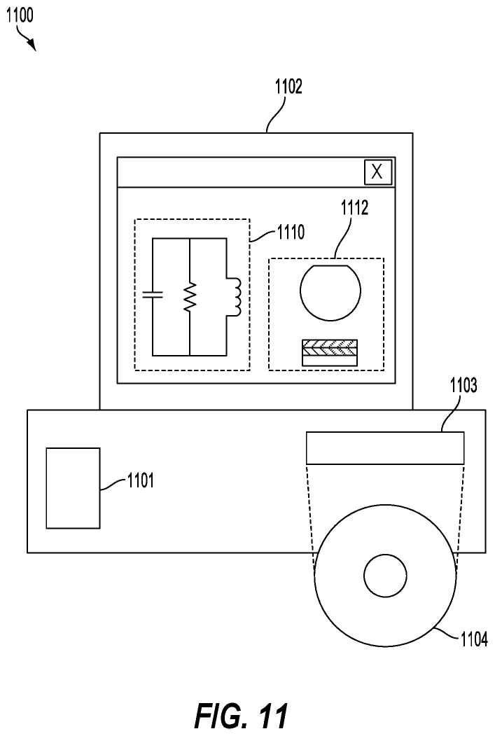

FIG. 11 is a block diagram illustrating a design workstation used for circuit, layout, and logic design of a stacked capacitor disclosed herein. A design workstation 1100 includes a hard disk 1101 containing operating system software, support files, and design software such as Cadence or OrCAD. The design workstation 1100 also includes a display 1102 to facilitate design of a circuit 1110 or the stacked capacitor. A storage medium 1104 is provided for tangibly storing the design of the circuit 1110 or the stacked capacitor. The design of the circuit 1110 or the stacked capacitor may be stored on the storage medium 1104 in a file format such as GDSII or GERBER. The storage medium 1104 may be a CD-ROM, DVD, hard disk, flash memory, or other appropriate device. Furthermore, the design workstation 1100 includes a drive apparatus 1103 for accepting input from or writing output to the storage medium 1104.

Data recorded on the storage medium 1104 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1104 facilitates the design of the circuit 1110 or the stacked capacitor.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communications networks and/or communications technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. In addition, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure provides certain example aspects and applications, other aspects that are apparent to t hose of ordinary skill in the art, including aspects, which do not provide all of the features and advantages set forth herein, are also within the scope of this disclosure. For example, the apparatuses, methods, and systems described herein may be performed digitally and differentially, among others. Accordingly, the scope of the present disclosure is intended to be defined only by reference to the appended claims.

1. An integrated circuit (IC) device, comprising:
a MOSCAP (metal-oxide-semiconductor capacitor) comprising a gate and source/drain (S/D) regions;
a MOMCAP (metal-oxide-metal capacitor) limited to be within a first four back-end-of-line (BEOL) layers on the MOSCAP, the MOMCAP comprising interdigitated fingers; and
a MIMCAP (metal-insulator-metal capacitor) in different BEOL layers than the MOMCAP, the MIMCAP comprising a dielectric between a plurality of plates.

2. The integrated circuit of claim 1, in which the MOSCAP comprises a first cathode and a first anode, the MOMCAP comprises a second cathode and a second anode, the MIMCAP comprises a third cathode and a third anode, in which the first anode, the second anode and the third anode are coupled together, and in which the first cathode, the second cathode, and the third cathode are coupled together.

3. The integrated circuit of claim 1, in which the MOMCAP is between the MOSCAP and the MIMCAP.

4. (canceled)

5. The integrated circuit of claim 1, in which the MOSCAP is coupled to the MIMCAP or the MOMCAP with multiple vias.

6. A method of fabricating a stacked capacitor, comprising:
fabricating a MOSCAP (metal-oxide-semiconductor capacitor) comprising a gate and source/drain (S/D) regions;
fabricating a MOMCAP (metal-oxide-metal capacitor) only within a first four back-end-of-line (BEOL) layers on the MOSCAP, the MOMCAP comprising interdigitated fingers; and
fabricating a MIMCAP (metal-insulator-metal capacitor) in different BEOL layers than the MOMCAP, the MIMCAP comprising a dielectric between a plurality of plates.

7. The method of claim 6, in which fabricating the MOSCAP comprises fabricating a first cathode and a first anode, in which fabricating the MOMCAP comprises fabricating a second cathode and a second anode, in which fabricating the MIMCAP comprises fabricating a third cathode and a third anode, in which the first anode, the second anode and the third anode are coupled together, and in which the first cathode, the second cathode, and the third cathode are coupled together.

8. The method of claim 6, in which fabricating the stacked capacitor comprises fabricating the MOMCAP between the MOSCAP and the MIMCAP.

9. (canceled)

10. The method of claim 6, further comprising coupling the MOSCAP to the MIMCAP or to the MOMCAP with multiple vias.

11. An integrated circuit (IC) device, comprising:
a MOSCAP (metal-oxide-semiconductor capacitor) comprising a gate and source/drain (S/D) regions;
a MOMCAP (metal-oxide-metal capacitor) limited to be within a first four back-end-of-line (BEOL) layers on the MOSCAP, the MOMCAP comprising interdigitated fingers; and
means for storing electrical charge, the electrical charge storing means in different BEOL layers than the MOMCAP, the electrical charge storing means located between the MOSCAP and the MOMCAP.

12. The integrated circuit of claim 11, in which the MOSCAP comprises a first cathode and a first anode, the MOMCAP comprises a second cathode and a second anode, the electrical charge storing means comprises a third cathode and a third anode, in which the first anode, the second anode and the third anode are coupled together, and in which the first cathode, the second cathode, and the third cathode are coupled together.

13. The integrated circuit of claim 11, in which the MOMCAP is between the MOSCAP and the electrical charge storing means.

14. (canceled)

15. The integrated circuit of claim 11, in which the MOSCAP is coupled to the electrical charge storing means or the MOMCAP with multiple vias.
